(19) United States
(12) Patent Application Publication
(10) Pub. No.: US 2018/0159070 A1
(43) Pub. Date: Jun. 7, 2018

(54) ORGANIC LIGHT EMITTING DIODE PACKAGE AND DISPLAY DEVICE COMPRISING THE SAME

(71) Applicant: Shenzhen China Star Optoelectronics Technology Co. Ltd., Shenzhen (CN)

(72) Inventor: Chao HE, Shenzhen (CN)

(73) Assignee: Shenzhen China Star Optoelectronics Technology Co. Ltd., Shenzhen (CN)

(21) Appl. No.: 14/897,506

(22) PCT Filed: Sep. 17, 2015
(86) PCT No.: PCT/CN2015/089840

§ 371 Date: Jun. 22, 2017

(30) Foreign Application Priority Data
Aug. 25, 2015 (CN) 201510524146.0

(51) Int. Cl. H01L 51/52; H01L 27/32

(52) U.S. Cl. CPC H01L 51/5246; H01L 27/3244

(57) ABSTRACT

Disclosed is an organic light emitting diode package which includes two oppositely disposed substrates, a containment region formed between the two oppositely disposed substrates, for accommodating an organic light emitting diode, and a blocking member provided around the containment region, for stopping an unwanted fluid. The blocking member is connected to one of the two substrates, and extends into a corresponding groove which is provided on the other substrate. The organic light emitting diode package is able to ensure good luminance quality of an OLED contained therein.

### CROSS-REFERENCE TO RELATED APPLICATIONS

The present application claims the priority of Chinese patent application CN201510524146.0, entitled “Organic light emitting diode package and display device comprising the same” and filed on Aug. 25, 2015, the entirety of which is incorporated herein by reference.

### TECHNICAL FIELD

The present disclosure relates to the technical field of display, and in particular, to an organic light emitting diode package. The present disclosure further relates to a display device comprising said organic light emitting diode package.

### TECHNICAL BACKGROUND

Organic light emitting diode (OLED) is a light emitting diode which emits light in response to an electric current. Use of OLEDs in a display device may save a backlight source, thus rendering the display device thinner and lighter.

However, in existing technologies, an OLED package is not capable of protecting an OLED from an unwanted fluid (e.g. water and/or oxygen, and so on). The unwanted fluid can easily seep into the OLED package, come into contact with the OLED contained in the OLED package, and damage the structure and performance of the OLED, thereby affecting luminance quality of the OLED. Therefore, OLED packages in existing technologies usually lead to poor luminance quality of an OLED contained therein, thus failing to satisfy users' requirements.

In view of the foregoing, it is therefore necessary to provide an OLED package capable of ensuring better luminance quality of an OLED contained therein.

### SUMMARY OF INVENTION

Directed against the above problem, the present disclosure provides an organic light emitting diode (OLED) package which can ensure better luminance quality of an OLED contained therein. The present disclosure further provides a display device which comprises said OLED package.

The present disclosure, at one aspect, provides an OLED package which comprises: two oppositely disposed substrates, a containment region formed between the two oppositely disposed substrates, for accommodating an OLED, and a blocking member provided around the containment region, for stopping an unwanted fluid. The blocking member is connected to one of the two substrates, and extends into a corresponding groove which is provided on the other substrate.

In the OLED package provided by the present disclosure, the blocking member can block the unwanted fluid and make it impossible for the unwanted fluid to directly enter into the containment region. The unwanted fluid can enter into the containment region only after rounding the blocking member. In this way, most of the unwanted fluid or almost all the unwanted fluid will be prevented from entering into the accommodation section, and therefore no damage will be caused to the OLED. Thus, the OLED will display a better luminance quality and will have a prolonged lifetime.

In one embodiment of the present disclosure, the groove has a bottom wall parallel to a surface of the substrate on which the groove is provided, and the blocking member extends towards the bottom wall of the corresponding groove, by means of which a seepage path of the unwanted fluid is lengthened and a gap between the blocking member and the bottom wall is reduced. In this manner, the unwanted fluid will be further prevented from entering into the containment region.

In one embodiment of the present disclosure, the blocking member is in contact with the bottom wall. With such a structure, the seepage path of the unwanted fluid will be blocked, and the unwanted fluid will thus be prevented from entering into the containment region.

In one embodiment, the blocking member is a frame that encloses the containment region. Such a blocking member will be able to stop the unwanted fluid coming from all directions, thus keeping the unwanted fluid out of the containment region more effectively.

In one embodiment of the present disclosure, a plurality of blocking members is provided along a direction parallel to surfaces of the substrates and towards the containment region. The plurality of blocking members is spaced apart from one another and each corresponds to a respective groove. Such a structure can further block the seeping of the unwanted fluid, and can prevent more unwanted fluid or even all of the unwanted fluid from entering into the containment region.

In one embodiment of the present disclosure, two adjacent blocking members are parallel to each other, in the direction parallel to the surfaces of the substrates and towards the containment region. Such a structure may render manufacturing of the OLED package easier.

In one embodiment of the present disclosure, two adjacent blocking members each are connected to a different substrate, in the direction parallel to the surfaces of the substrates and towards the containment region. In this way, the seepage path of the unwanted fluid can further be lengthened. Consequently, much more unwanted fluid or all the unwanted fluid will be prevented from entering into the containment region.

In one embodiment of the present disclosure, a sealing frame is provided between the two oppositely disposed substrates, for joining the two substrates together. The containment region is enclosed by the sealing frame. The blocking member is disposed in an area provided with the sealing frame, and is enclosed by the sealing frame. The sealing frame joins the two oppositely disposed substrates together, and the blocking member prevents the unwanted fluid from entering into the containment region. Furthermore, such arrangement enables the sealing frame and the blocking member to occupy a smaller space and the substrates to occupy a smaller area. In this case, the OLED package can be manufactured smaller, or, with the volume and area of the OLED package being the same, the volume and area of the containment region can be larger.

In one embodiment of the present disclosure, a width of the blocking member occupies 10% to 40% of a width of the area provided with the sealing frame between the two substrates, in the direction parallel to surfaces of the substrates and towards the containment region. Such a structure can ensure that the unwanted fluid is stopped and meanwhile the sealing frame joins the two substrates firmly together.

The present disclosure, as another aspect, provides a display device which comprises the above-said OLED package. The display device using said OLED package will have better display quality and a longer lifetime.

Compared with the existing technologies, the present disclosure achieves the following beneficial effects. (1) The blocking member can block the unwanted fluid and render it impossible for the unwanted fluid to directly enter into the containment region. The unwanted fluid can enter into the containment region only after rounding the blocking member. (2) Most of or almost all the unwanted fluid will be prevented from entering into the containment region, and therefore no damage will be caused to the OLED. The lifetime of the OLED can thus be prolonged. (3) The OLED can have a better luminance quality.

### BRIEF DESCRIPTION OF THE DRAWINGS

The present disclosure will be explained further in detail below based on the embodiments and in conjunction with the accompanying drawings.

FIG. 1 schematically shows the structure of an OLED package according to an embodiment of the present disclosure;

FIG. 2 schematically shows the structure of a part of the OLED package in FIG. 1 according to an embodiment of the present disclosure;

FIG. 3 schematically shows the structure of a blocking member in FIG. 1 according to an embodiment of the present disclosure;

In the drawings, same components are represented with same references. The drawings are not drawn according to actual ratio.

### DETAILED DESCRIPTION OF THE EMBODIMENTS

The present disclosure will be explained in detail below with reference to the accompanying drawings.

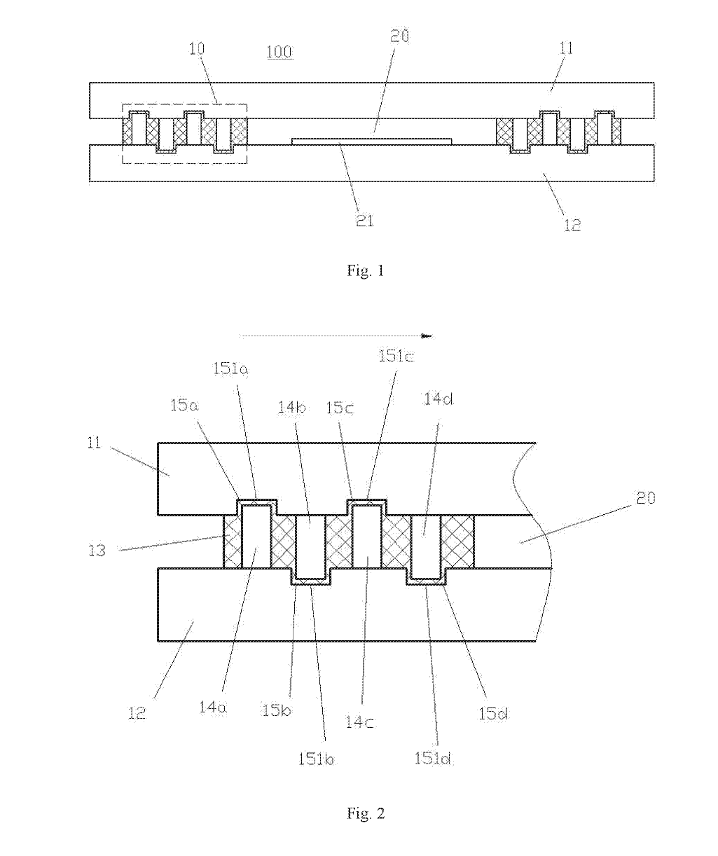

FIG. 1 schematically shows the structure of an organic light emitting diode (OLED) package 100.

The OLED package 100 comprises oppositely disposed substrates 11, 12. For sake of description, the substrates 11, 12 will be referred to as the first substrate 11 and the second substrate 12, respectively. A containment region 20 is formed between the first substrate 11 and the second substrate 12. An OLED 21 can be provided in the containment region 20.

A blocking member is provided around the containment region 20 provided between the first substrate 11 and the second substrate 12. The blocking member is made of a material capable of stopping an unwanted fluid. The unwanted fluid is usually oxygen and/or water vapor. In this case, the blocking member can be made of a silicon nitride material, silica material, or other compact materials.

As shown in FIG. 2, the blocking member is connected to one of the two substrates. A groove corresponding to the blocking member is provided on the other substrate. The groove has an opening facing the blocking member and the substrate on which the blocking member is provided, such that the blocking member can extend into the groove.

In one embodiment, the blocking member can be connected to the first substrate 11. An example can be found with the blocking member 14b in FIG. 2. In this case, a groove 15b corresponding to the blocking member 14b is provided on the second substrate 12. The blocking member 14b inserts into the groove 15b.

In another embodiment, the blocking member can be connected to the second substrate 12. An example can be found with the blocking member 14a in FIG. 2. In this case, a groove 15a corresponding to the blocking member 14a is provided on the first substrate 11. The blocking member 14a. inserts into the groove 15a.

By providing the above structure, the unwanted fluid will be blocked by the blocking member, and will not be able to, along a direction indicated by the arrow in FIG. 2 (a direction parallel to surfaces of the substrates and towards the containment region), directly pass through an area where the blocking member is provided and seep into the containment region 20. Such a structure greatly reduces a flowing area of a seepage path of the unwanted fluid, and enables most of the unwanted fluid to be kept out of the containment region 20. In this way, only a small part of the unwanted fluid can seep into the containment region 20 through an area where no blocking member is provided. In addition, the seepage path of the unwanted fluid is also lengthened because the unwanted fluid can flow into the containment region 20 only after rounding the blocking member. This renders the seepage path circuitous, and hence can further prevent more unwanted fluid from entering into the containment region 20.

The above structure is also able to effectively prevent an unwanted gas from coming into contact with the OLED 21 contained in the containment region, thereby ensuring normal operation of the OLED 21, and further enabling the OLED to have a better luminance quality and a longer lifetime. Users' requirements for OLED packages can thus be satisfied.

In order to block the unwanted gas more effectively, the blocking member can be configured to extend into the groove and towards a bottom wall of the groove. As shown in FIG. 2, the groove 15a has a bottom wall 151a which is parallel or substantially parallel to a surface of the first substrate 11 which faces the second substrate 12. The blocking member 14a extends towards the bottom wall 151a, so that a distance between the blocking member 14a and the bottom wall 151a is decreased as much as possible. In this manner, the flowing area of the seepage path of the unwanted fluid can be further reduced, and the unwanted fluid will be further prevented from entering into the containment region 20.

Preferably, the blocking member can extend to be in contact with the bottom wall. That is to say, for the blocking member 14a, an idea arrangement is that the blocking member 14a extends into the groove 15a and comes into contact with the bottom wall 151a. In this way, the unwanted gas will be completely kept out of the containment region 20.

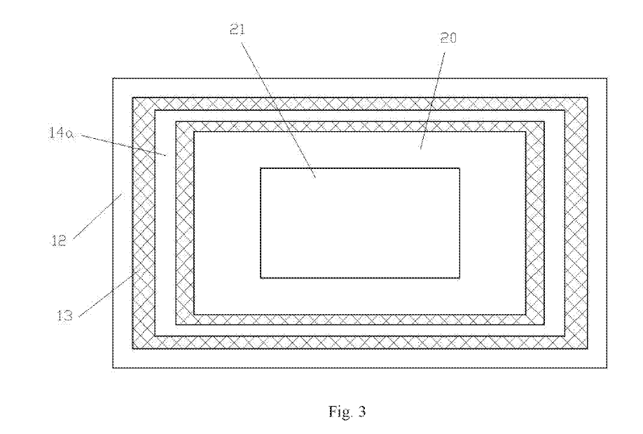

Furthermore, as shown in FIG. 3, the blocking member (e.g. the blocking member 14a) can be a frame which encloses the containment region 20 and the OLED 21 contained in the containment region. The shape of the frame can be rectangular, round or irregular, and depends upon application.

Preferably, as shown in FIG. 1, a plurality of blocking members 14a, 14b, 14c, 14d is provided along the direction parallel to surfaces of the substrates and towards the containment region. Grooves 15a, 15b, 15c, 15d each corresponding to a respective one of the blocking members 14a, 14b, 14c, 14d are also provided. The blocking members 14a, 14b, 14c, 14d are spaced apart from one another. This structure can further keep the unwanted gas out of the containment region 20.

It should be noted that the blocking members 14a, 14b, 14c, 14d can all be provided on the first substrate 11, with the grooves 15a, 15b, 15c, 15d all being provided on the second substrate 12. Or, the blocking members 14a, 14b, 14c, 14d can all be provided on the second substrate 12, with the grooves 15a, 15b, 15c, 15d all being provided on the first substrate 11.

Preferably, along the direction parallel to surfaces of the substrates and towards the containment region, one or more of the blocking members 14a, 14b, 14c, 14d can be provided on the first substrate 11, and meanwhile other blocking members are provided on the second substrate 12. In this case, the grooves 15a, 15b, 15c, 15d each corresponding to a respective blocking member are provided on a corresponding substrate. Such structure will render the seepage path of the unwanted fluid longer and more circuitous.

More preferably, two adjacent blocking members each can be connected to a different substrate. That is to say, as shown in FIG. 1, the blocking members 14a, 14c are provided on the second substrate 12, and the blocking members 14b, 14d are provided on the first substrate 11. The grooves 15a, 15b, 15c, 15d each are provided to correspond to a respective one of the blocking members. Such a zigzagging structure will render the seepage path of the unwanted fluid much longer and much more circuitous.

It should be noted that the blocking members 14a, 14b, 14c, 14d can each extends into a respective one of the grooves 15a, 15b, 15c, 15d, and come into contact with a respective one of bottom walls 151a, 151b, 151c, 151d. Or, only one or more of the blocking members 14a, 14b, 14c, 14d each extend into a respective groove, and come into contact with a respective bottom wall.

In addition, as shown in FIG. 2, a sealing frame 13 can also be provided between the oppositely disposed first and second substrate 1, 2. The sealing frame, as shown in FIG. 3, has a frame structure, and encloses the containment region. In this way, the first substrate 11 and the second substrate 12 can be joined firmly together to form the containment region 20 which holds the OLED 21 safely.

As shown in FIGS. 1 and 2, the blocking member is located within an area provided with the sealing frame 13. Such an arrangement enables the sealing frame and the blocking member to occupy a relatively small space and can reduce the area of the substrates, whereby the OLED package can be manufactured smaller to facilitate use of it. Or, with the volume and area of the OLED package remaining the same, such an arrangement can cause the containment region 20 to occupy a larger space and area.

In this case, the blocking member is enclosed by the sealing frame 13. Besides, when the groove is not fully filled with the respective blocking member, the sealing frame 13 can extend into the groove and fill the groove. For example, in the case that a gap is provided between the blocking member and the bottom wall of the groove, the sealing frame 13 can extend into the gap. Such a structure can improve the steadiness of the connection between the two oppositely disposed substrates (i.e., the first substrate 11 and the second substrate 12).

Preferably, in the direction parallel to surfaces of the substrates and towards the containment region, a total width of the blocking members occupies 10% to 40% of a width of the area provided with the sealing frame between the two substrates. Such a structure can ensure that the substrates are joined firmly together by the sealing frame while the unwanted fluid is stopped.

In addition, in the direction parallel to the surfaces of the substrates and towards the containment region, two adjacent blocking members can be parallel to each other, which can facilitate the manufacturing of the OLED package 100. The blocking members can also be provided in an inclined manner or cross one another, which depends upon application. In the case that the blocking members are provided in the area 10 provided with the sealing frame, any feasible topological structure can be formed with the blocking members as nodes and the sealing frame as a connecting medium.

The OLED package 100 can be manufactured according to the following method steps.

In step 1, one or more grooves are formed, by etching, at an area of a substrate (a first substrate 11 and/or a second substrate 12) where a sealing frame is to be provided.

In step 2, a blocking member facing and corresponding to the groove is provided at a corresponding area on the substrate (the first substrate 11 and/or the second substrate 12).

The specific position and structure of the groove and the corresponding blocking member can be determined based on the above description about the structure of the OLED package 100 and users' requirements.

In step 3, an ultraviolet curing adhesive is provided on the substrate provided with the groove and/or the blocking member. Preferably, the ultraviolet curing adhesive is provided on the substrate which is disposed relatively as a lower substrate when the OLED package is manufactured, the ultraviolet curing adhesive covering the groove formed on said substrate and the blocking member provided on said substrate.

In step 4, the two substrates (the first substrate 11 and/or the second substrate 12) are disposed opposite to each other such that the blocking member can insert into the corresponding groove by a predetermined depth.

In step 5, the ultraviolet curing adhesive is solidified by being exposed to ultraviolet irradiation to form the sealing frame 13 which joins the substrates together (the first substrate 11 and/or the second substrate 12).

The above OLED package 100 or the OLED package 100 manufactured according to the above method can keep the unwanted fluid out of the containment region 20, thus ensuring the luminance quality of the OLED and prolonging the lifetime of the OLED.

In addition, use of the above OLED package 100 or the OLED package 100 manufactured according to the above method in a display device can enable the display device to have a better luminance quality and a longer lifetime.

It should be noted herein that the OLED package 100 or the display device may further comprise any other components which are well-known to one skilled person in the art and necessary to achieve normal operation of the OLED package 100 or the display device.

The above details are only descriptions on preferred embodiments of the present disclosure. Any improvements on the implementing forms or substitutions of the components thereof with equivalents can be made or done without departing from the scope of the present disclosure. It should be noted that as long as there is no structural conflict, any of the embodiments and any of the technical features thereof may be combined with one another. The present disclosure is not limited to any disclosed embodiment, and comprises all technical solutions falling within the scope of the present disclosure.

1. An organic light emitting diode package, comprising:
two oppositely disposed substrates, a containment region formed between the two oppositely disposed substrates, for accommodating an organic light emitting diode, and a blocking member provided around the containment region, for stopping an unwanted fluid,
wherein the blocking member is connected to one of the two substrates, and extends into a corresponding groove which is provided on the other substrate.

2. The organic light emitting diode package according to claim 1, wherein the groove has a bottom wall parallel to a surface of the substrate on which the groove is provided, and the blocking member extends towards the bottom wall of the corresponding groove.

3. The organic light emitting diode package according to claim 2, wherein the blocking member is in contact with the bottom wall.

4. The organic light emitting diode package according to claim 1, wherein the blocking member is a frame that encloses the containment region.

5. The organic light emitting diode package according to claim 1, wherein a plurality of blocking members is provided along a direction parallel to surfaces of the substrates and towards the containment region, the plurality of blocking members being spaced apart from one another and each corresponding to a respective groove.

6. The organic light emitting diode package according to claim 5, wherein two adjacent blocking members are parallel to each other in the direction parallel to the surfaces of the substrates and towards the containment region.

7. The organic light emitting diode package according to claim 5, wherein two adjacent blocking members each are connected to a different substrate, in the direction parallel to the surfaces of the substrates and towards the containment region.

8. The organic light emitting diode package according to claim 1, wherein a sealing frame is provided between the two oppositely disposed substrates, for joining the two substrates together, the sealing frame enclosing the containment region, and
the blocking member is disposed in an area provided with the sealing frame, and is enclosed by the sealing frame.

9. The organic light emitting diode package according to claim 8, wherein a width of the blocking member occupies 10% to 40% of a width of the area provided with the sealing frame between the two substrates, in a direction parallel to surfaces of the substrates and towards the containment region.

10. A display device, comprising an organic light emitting diode package,
wherein the organic light emitting diode package comprises: two oppositely disposed substrates, an containment region formed between the two oppositely disposed substrates, for accommodating an organic light emitting diode, and a blocking member provided around the containment region, for stopping an unwanted fluid, and
wherein the blocking member is connected to one of the two substrates, and extends into a corresponding groove which is provided on the other substrate.

11. The display device according to claim 10, wherein the groove has a bottom wall parallel to a surface of the substrate on which the groove is provided, and the blocking member extends towards the bottom wall of the corresponding groove.

12. The display device according to claim 11, wherein the blocking member is in contact with the bottom wall.

13. The display device according to claim 10, wherein the blocking member is a frame that encloses the containment region.

14. The display device according to claim 10, wherein a plurality of blocking members is provided along a direction parallel to surfaces of the substrates and towards the containment region, the plurality of blocking members being spaced apart from one another and each corresponding to a respective groove.

15. The display device according to claim 14, wherein two adjacent blocking members are parallel to each other in the direction parallel to the surfaces of the substrates and towards the containment region.

16. The display device according to claim 14, wherein two adjacent blocking members each are connected to a different substrate, in the direction parallel to the surfaces of the substrates and towards the containment region.

17. The display device according to claim 10, wherein a sealing frame is provided between the two substrates, for joining the two substrates together, the sealing frame enclosing the containment region, and
the blocking member is disposed in an area provided with the sealing frame, and is enclosed by the sealing frame.

18. The display device according to claim 17, wherein a width of the blocking member occupies 10% to 40% of a width of the area provided with the sealing frame between the two substrates, in a direction parallel to surfaces of the substrates and towards the containment region.
